(19) United States
(12) Patent Application Publication
(10) Pub. No.: US 2021/0013843 A1
(43) Pub. Date: Jan. 14, 2021

(54) CROSSTALK CANCELLATION FOR DIGITAL PREDISTORTION FEEDBACK LOOP

(71) Applicant: Apple Inc., Cupertino, CA (US)

(72) Inventors: Alon Cohen, Petach Tikva (IL); Ilia Yoffe (Iofedov), Ashdod (IL); Miki Genossar, Modlin Maccabim Reut (IL); Jeremy Stein, Haifa (IL)

(21) Appl. No.: 16/977,566

(22) PCT Filed: Mar. 29, 2018
(86) PCT No.: PCT/US2018/025009

§ 371 Date: Sep. 2, 2020

(51) Int. Cl. H03F 1/32; H03F 3/189; H04B 1/40; H03F 3/24

(52) U.S. Cl. CPC H03F 1/3247; H03F 3/189; H03F 2200/451; H03F 3/24; H04B 1/40

(57) ABSTRACT

Systems, methods, and circuitries are disclosed to determine parameters for predistortion circuitry in a transceiver including a transmit chain and a receive chain. In one example, a method includes providing a training signal to a power amplifier on the transmit chain. A separation circuitry is controlled to provide an amplified training signal and a first feedback signal is received from the receive chain. The separation circuitry is controlled to output a modified amplified training signal and a second feedback signal is received from the receive chain. Parameters for the predistortion circuitry are determined based the first feedback signal and the second feedback signal.

### BACKGROUND

Digital predistortion (DPD) is widely used in communication systems to improve the power efficiency of nonlinear power amplifiers (PAs) in transceivers. A digital predistortion system compensates for a PA's nonlinearity by applying an inverse nonlinear characteristic to the signal being amplified by the PA. To determine a particular PA's nonlinearity, the digital predistortion system is trained. The training is done by providing a training signal to the PA and using a feedback signal which takes the transmit signal from the PA's output and brings it to the digital domain using a receiver chain of the transceiver.

### BRIEF DESCRIPTION OF THE DRAWINGS

FIG. 1 illustrates an example of crosstalk interference that occurs during predistortion training.

FIGS. 2 and 2A illustrate a transceiver training system that includes example training circuitry and separation circuity in accordance with various aspects described.

FIG. 3 illustrates an exemplary transceiver training system that includes example correction circuitry in accordance with various aspects described.

FIG. 4 illustrates an exemplary transceiver training system that includes example training circuitry and separation circuity in accordance with various aspects described.

FIG. 5 illustrates a flow diagram of an example method of determining DPD parameters based on two feedback signals in accordance with various aspects described.

### DESCRIPTION

Predistortion may be accomplished by hardware or circuitry and/or a combination of hardware and software, such as a DPD module. For the purposes of this description, DPD circuitry will be performing the predistortion based on the parameters determined by the training systems described herein. However, a DPD module or any other DPD system may utilize the parameters that are determined by the training systems described herein.

Training of DPD circuitry in a transceiver involves determining various parameters of the predistortion circuitry based on a training signal. For example, during training weights or coefficients may be determined that are used to weight different components of the transmit signal to cancel anticipated interference during normal operation. During the training of the digital predistortion circuitry there is crosstalk between the transmit chain carrying the training signal and resulting transmit signal and the receiver chain carrying the feedback signal of the transmit signal.

This crosstalk interferes in the measurement of the PA's feedback signal, making it difficult to isolate the nonlinearities of the PA, which are to be canceled by the digital predistortion circuitry, from the crosstalk effects from the receiver chain, which may not be present during normal operation of the transceiver. The crosstalk problem becomes critical in the modern transceiver systems that are based on the mmWave protocols such as 5G or WiGig. This is because in mmWave systems there is very low isolation between the transmitter and receiver due to the high carrier frequency as well as a memory effect due to the wide bandwidth of the transmit signal. Further, mmWave systems often use multi-stage PAs instead of one PA which introduces further crosstalk interference from various stages of the transmit chain.

Existing systems with DPD mechanisms that operate in sub 6 GHz frequencies do not suffer from low transmit to receive isolation. Further, systems that operate at higher frequencies (mmWave) but have an external (off-chip) PA do not experience the isolation problem. However, the design trend is to use an integrated PA in 5G mmWave RF chip and to implement digital predistortion circuitry on the RF chip to get better power efficiency. Thus, the issue of crosstalk effects on the feedback signal during DPD training becomes a significant design challenge.

Described herein are predistortion training systems, methods, modules and circuitries that include separation circuitry and training circuitry or processor-executable instructions configured to cancel crosstalk effects from the feedback signal during DPD training. The separation circuitry is disposed in a training feedback path that feeds an amplified training signal to the training circuitry by way of a receive chain. The separation circuitry operates at radio frequency (RF) to selectively generate a modified amplified training signal that is also provided to the receive chain. The digital training circuitry controls the separation circuitry to selectively generate the modified amplified training signal or to simply output the amplified training signal. The training circuitry processes a first feedback signal that results from the feeding back of the amplified training signal and a second feedback signal that results from the feeding back of the modified amplified training signal to isolate the crosstalk effect from the effects of PA nonlinearities in the first feedback signal.

The present disclosure will now be described with reference to the attached figures, wherein like reference numerals are used to refer to like elements throughout, and wherein the illustrated structures and devices are not necessarily drawn to scale. As utilized herein, terms “module”, “component,” “system,” “circuit,” “element,” “slice,” “circuitry,” and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term “set” can be interpreted as “one or more.”

As another example, circuitry or similar term can be an apparatus with specific functionality provided by mechanical parts operated by electric or electronic circuitry, in which the electric or electronic circuitry can be operated by a software application or a firmware application executed by one or more processors. The one or more processors can be internal or external to the apparatus and can execute at least a part of the software or firmware application. As yet another example, circuitry can be an apparatus that provides specific functionality through electronic components without mechanical parts; the electronic components can include one or more processors therein to execute executable instructions stored in computer readable medium and/or firmware that confer(s), at least in part, the functionality of the electronic components.

It will be understood that when an element is referred to as being “connected” or “coupled” to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electro-magnetic wave in the other element without physical contact or intervening components. Further, when a voltage, current, or signal is referred to as being “applied” to an element, the voltage, current, or signal may be conducted to the element by way of a physical connection or by way of capacitive, electro-magnetic, or inductive coupling that does not involve a physical connection.

Use of the word exemplary is intended to present concepts in a concrete fashion. The terminology used herein is for the purpose of describing particular examples only and is not intended to be limiting of examples. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

In the following description, a plurality of details is set forth to provide a more thorough explanation of the embodiments of the present disclosure. However, it will be apparent to one skilled in the art that embodiments of the present disclosure may be practiced without these specific details. In other instances, well-known structures and devices are shown in block diagram form rather than in detail in order to avoid obscuring embodiments of the present disclosure. In addition, features of the different embodiments described hereinafter may be combined with each other, unless specifically noted otherwise.

FIG. 1 illustrates a transceiver 100 operating in a training mode in which a training signal z(t) is provided to multiple PA stages (PA₁-PA_{N}) in the transceiver's transmit chain. For the purposes of this description, multiple PA stages are included in the transmit chain, however, in one example, only a single PA stage is included in the transmit chain. The final PA stage outputs an amplified training signal s(t) which includes effects of nonlinearities in the amplifier stages. Assuming a memoryless model for each PA of the chain, the output of each one of the PAs can be modeled as:

sₙ(t)=Σₖ₌₁^{K}αₖz(t)|z(t)|^{2(k-1)} EQ 1

Similar analysis can be performed, assuming a PA model with memory such as memory polynomial or Volterra series.

The signal obtained at the output of the whole chain is denoted by s(t). The amplified training signal s(t) is returned by a feedback path that includes the transceiver's receive chain. The feedback signal y(t) is used by training circuitry 120 to determine parameters (e.g., coefficients) for digital predistortion circuitry 110. Ideally, the feedback signal y(t) would be very close to the amplified training signal s(t) so that training would be based in the main on the PA nonlinearities. However, as discussed above, in mmWave systems that use an integrated PA, there may be significant crosstalk between the receive chain and the transmit chain as shown schematically in FIG. 1 as the dashed lines between the transmit chain and the receive chain.

In FIG. 1, wₙ(t) is the crosstalk component of the feedback signal from the n^{th} PA of the chain to the feedback path. The model of this signal is given by:

wₙ(t)=βₙsₙ(t−τₙ) EQ 2

where τₙ is time delay from the n-th PA and βₙ is coupling coefficient. The total crosstalk signal seen at the output of the feedback path is:

w(t)=Σₙwₙ(t) EQ 3

For general case of the nonlinear crosstalk, this signal is given by:

w(t)=Σₖ₌₁^{K}Σₙ₌₁^{N}βₙₖz(t−τₙ)|z(t−τₙ)|^{2(k-1)} EQ 4

For the special case of the linear cross talk, this signal is given by:

w(t)=Σₙ₌₁^{N}βₙz(t−τₙ) EQ 5

Thus the feedback signal y(t) includes the amplified training signal s(t) that includes the effects of PA nonlinearities (hereinafter referred to as a “PA nonlinearity component” of the feedback signal) and also a crosstalk component w(t):

y(t)=s(t)+w(t) EQ 6

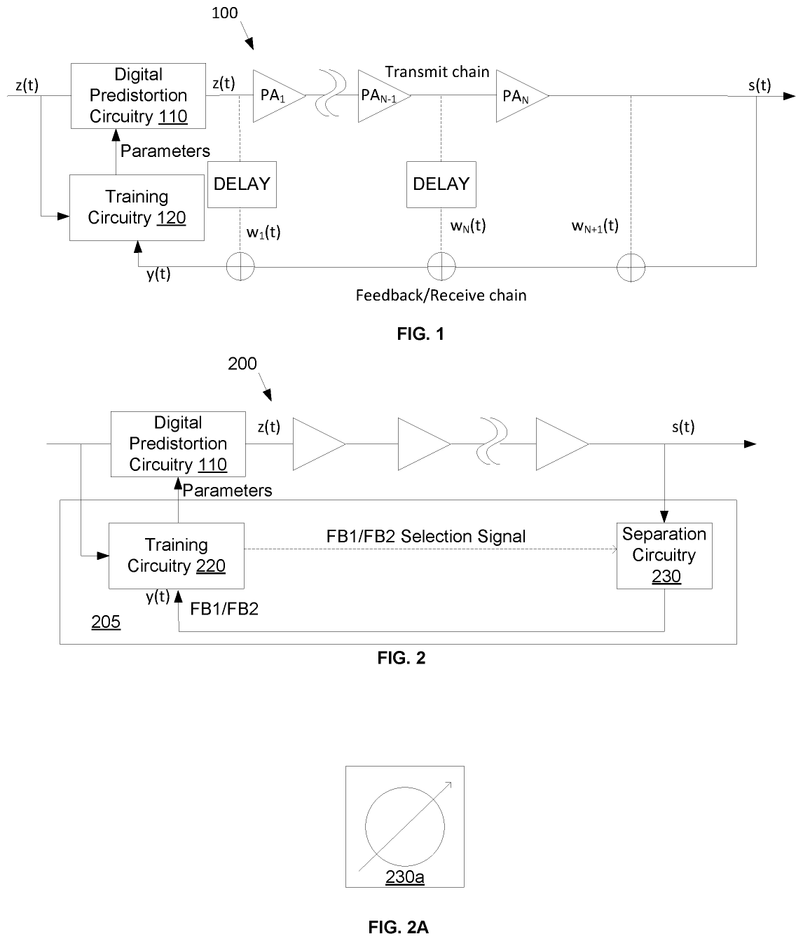

FIG. 2 illustrates an exemplary transceiver 200 that includes an example predistortion training system 205 that determines parameters, such as coefficients, for digital predistortion circuitry 110. The predistortion training system 205 includes training circuitry 220 and separation circuitry 230. The training circuitry 220 is in the digital domain and provides a selection signal to the separation circuitry 230. The selection signal controls the separation circuitry to operate in a first mode or a second mode. The separation circuitry 230 is in the RF domain and is controlled by the training circuitry 220 to, in the first mode, output, without modification, the amplified training signal s(t) to the receive chain. In the second mode the separation circuitry 230 generates a modified amplified training signal and outputs the modified amplified training signal to the receive chain. When the separation circuitry 230 outputs the amplified training signal, the training circuitry 220 receives a first feedback signal (FB1). When the separation circuitry generates and outputs the modified amplified training signal, the training circuitry 220 receives a second feedback signal (FB2). The training circuitry 220 determines the DPD parameters based on both the first feedback signal and the second feedback signal.

Referring now to FIG. 2A, in one example, separation circuitry 230a includes a phase shifter that shifts the phase of the amplified training signal by Θ to generate the modified amplified training signal. The phase shifter can be enabled (i.e., to operate in the second mode) or disabled (i.e., to operate in the first mode) by the training circuitry 220 with the selection signal. Returning to FIG. 2, when the phase shifter is enabled the feedback signal (i.e., the second feedback signal FB2) at the output of the feedback path is given by

y₂(t)=s(t)e^{jθ}+w(t). EQ 7

During training, the training signal z(t) is provided twice to the amplifier stages in the transmit chain. The first time the training signal is provided to the transmit chain, the training circuitry 220 controls the separation circuitry 230 to pass the amplified training signal, without modification (i.e., the phase shifter is disabled) and the first feedback signal is:

y₁(t)=s(t)+w(t) EQ 8

The second time the training signal is provided to the transmit chain, the training circuitry 220 controls the separation circuitry 230 to enable the phase shifter to shift the amplified training signal s(t) by θ. This second feedback signal is:

y₂(t)=s(t)e^{jθ}w(t) EQ 9

A vector representation of the first feedback signal and the second feedback signal is:

$$[ \begin{matrix}{y}_{1} ( t ) \\ {y}_{2} ( t )\end{matrix} ] = [ \begin{matrix}1 & 1 \\ {e}^{j θ} & 1\end{matrix} ] [ \begin{matrix}s ( t ) \\ w ( t )\end{matrix} ] \qquad EQ 9$$

For Θ≠0 the matrix is invertible, and therefore the PA nonlinearity component s(t) can be separated from the crosstalk component w(t) in the feedback signals y₁(t) and y₂(t). The training circuitry 220 uses this principle to determine the PA nonlinearity component and the crosstalk component of the feedback signals.

In one example, the training circuitry 220 determines the parameters for the digital predistortion circuitry 110 using the PA nonlinearity component s(t) directly for the DPD training. In this example, the training circuitry 220 iteratively adjusts the parameters and measures an error between the training signal z(t) and the PA nonlinearity component. The parameter values that minimize the error are provided to the predistortion circuitry 110. In one example, the training circuitry 220 uses a least squares algorithm to determine the parameters that minimize the error. In one example, the training circuitry 220 is implemented in a baseband processor executing stored instructions to determine the PA nonlinearity component and the crosstalk component as just described with reference to equation 9.

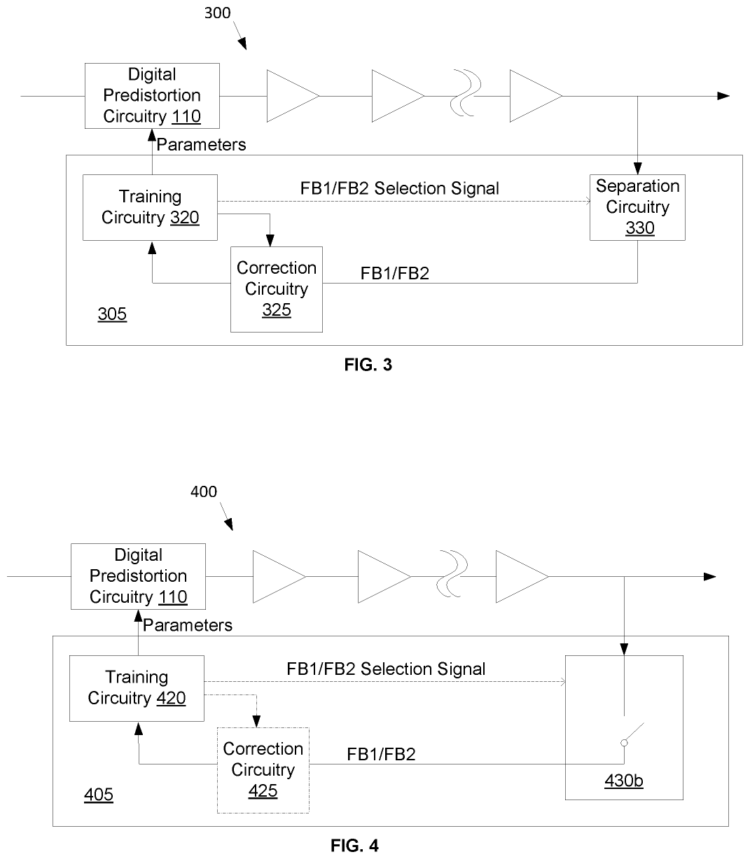

FIG. 3 illustrates in example transceiver 300 that includes an example predistortion training system 305 that determines parameters, such as coefficients, for digital predistortion circuitry 110. The predistortion training system 305 includes training circuitry 320 and separation circuitry 330. The training circuitry 320 and the separation circuitry 330 operate similarly to the training circuitry 220 and the separation circuitry 230 of FIG. 2 to determine the PA nonlinearity component and the crosstalk component of the first feedback signal using the first feedback signal and the second feedback signal.

In the example of FIG. 3, however, the training circuitry 330 does not use the PA nonlinearity component directly to determine the predistortion parameters in every training iteration. Instead, the training circuitry 330 uses the crosstalk signal w(t) to estimate model parameters of a crosstalk model that simulates the crosstalk signal. The training circuitry 330 adapts correction circuitry 325 to simulate and cancel the crosstalk component from future feedback signals. At the output of the correction circuitry 325 there will be the “pure” PA nonlinearity component of the amplified training signal without the crosstalk component.

In this manner, once the crosstalk model is estimated in a first training iteration, the crosstalk component of the amplified training signal can be subtracted from the received signal y(t) by the correction circuitry 325 in a second or any subsequent training iteration without having to re-calculate the crosstalk component using the separation circuitry 330. The training circuitry 320 iteratively adjusts the parameters and measures an error between the training signal z(t) and the PA nonlinearity component output by the correction circuitry 325. The parameter values that minimize the error are provided to the predistortion circuitry 110. In one example, the training circuitry 320 uses a least squares algorithm to determine the parameters that minimize the error. In one example, the training circuitry 320 is implemented in a baseband processor executing stored instructions to determine the PA nonlinearity component and the crosstalk component as described with reference to equation 9.

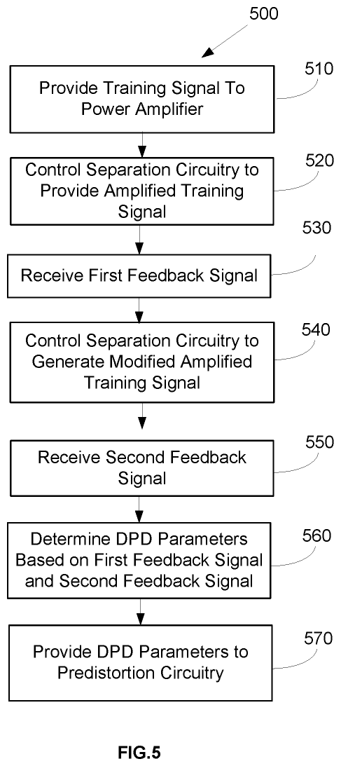

FIG. 4 illustrates in example transceiver 400 that includes an example predistortion training system 405 that determines parameters, such as coefficients, for digital predistortion circuitry 110. The predistortion training system 405 includes training circuitry 420 and separation circuitry 430. In the predistortion training system 405, the separation circuitry 430 includes a switch that is controlled by the training circuitry 420 operate in a closed condition (i.e., the first mode of operation) in which the amplified training signal is provided to the receive chain or in an open condition (i.e., the second mode of operation) in which the amplified training signal is not provided to the receive chain.

When the switch is closed while the training signal is being amplified by the amplifiers in the transmit chain, the feedback signal (e.g., the first feedback signal) includes both the amplified training signal/PA nonlinearity component s(t) and the crosstalk component w(t). When the switch 430 is open while the training signal is being amplified by the amplifiers in the transmit chain, the amplified training signal is disconnected from the receive chain, thus removing the amplified training signal from the feedback signal, so that only the crosstalk signal w(t) will be present in the feedback signal (e.g., the second feedback signal). The training circuitry 420 is configured to subtract the second feedback signal from the first feedback signal to isolate the “pure” amplified training signal or PA nonlinearity component s(t).

In one example, the training circuitry 420 determines the parameters for the digital predistortion circuitry 110 using the PA nonlinearity component s(t) directly for the DPD training. In this example, the training circuitry 420 iteratively adjusts the parameters and measures an error between the training signal z(t) and the PA nonlinearity component. The parameter values that minimize the error are selected and provided to the predistortion circuitry 110. In one example, the training circuitry 420 uses a least squares algorithm to determine the parameters that minimize the error.

In another example, the training circuitry 430 does not use the PA nonlinearity component directly to determine the predistortion parameters. Instead, the training circuitry 430 uses the crosstalk signal w(t) to find parameters of a crosstalk model that simulates the crosstalk signal. The training circuitry 430 adapts correction circuitry 425 (shown in dashed line in FIG. 4 to indicate an optional element) to simulate and cancel the crosstalk component from future feedback signals. At the output of the correction circuitry 425 there will be the “pure” PA nonlinearity component of the amplified training signal without the crosstalk component.

In this manner, once the crosstalk model is estimated the crosstalk component of the amplified training signal can be subtracted from the received signal y(t) by the correction circuitry in subsequent training without having to re-calculate the crosstalk component using the separation circuitry 430. The training circuitry 420 iteratively adjusts the parameters and measures an error between the training signal z(t) and the PA nonlinearity component output by the correction circuitry 425. The parameter values that minimize the error are provided to the predistortion circuitry 110. In one example, the training circuitry 420 uses a least squares algorithm to determine the parameters that minimize the error. In one example, the training circuitry 420 is implemented in a baseband processor executing stored instructions to determine the PA nonlinearity component and the crosstalk component as just described.

FIG. 5 illustrates a flow diagram outlining an example method 500 for determining parameters for predistortion circuitry. At least portions of the method 500 may be performed, for example, by training circuitry 220 and/or 320 of FIGS. 2 and 3, respectively. At 510, the method includes providing a training signal to a power amplifier (or in one example, multiple stages of power amplifiers). In one example the training signal may be generated by a baseband processor operating in a training mode to generate a predetermined training signal or series of training signals. At 520, separation circuitry is controlled to provide an amplified training signal. At 530, a first feedback signal is received that corresponds to the amplified training signal fed back through a receiver chain of the transceiver. The first feedback signal includes a PA nonlinearity component and a crosstalk component.

At 540, the method includes controlling the separation circuitry to generate a modified amplified training signal. In one example the modified amplified training signal is a phase shifted version of the amplified training signal. In another example, the modified amplified training signal includes a signal in which the amplified training signal has been removed. At 550, a second feedback signal is received. The second feedback signal corresponds to the modified amplified training signal fed back through the receiver chain of the transceiver. At 560, the method includes determining DPD parameters based on the first feedback signal and the second feedback signal. At 570 the parameters are provided to predistortion circuitry.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention.

Examples can include subject matter such as a method, means for performing acts or blocks of the method, at least one machine-readable medium including instructions that, when performed by a machine cause the machine to perform acts of the method or of an apparatus or system determining DPD coefficients using a first feedback signal and a second feedback signal according to embodiments and examples described herein.

Example 1 is a predistortion training system for a predistortion circuitry in a transceiver, including separation circuitry and training circuitry. The separation circuitry is configured to, in a first mode, provide an amplified training signal to a receive chain of the transceiver, wherein the amplified training signal corresponds to a training signal amplified by a power amplifier in a transmit chain of the transceiver; and, in a second mode, process the amplified training signal to generate a modified amplified training signal and provide the modified amplified training signal to the receive chain of the transceiver. The training circuitry is configured to receive a first feedback signal that includes the amplified training signal from the receive chain; receive a second feedback signal that includes the modified amplified training signal from the receive chain; determine parameters for the predistortion circuitry based at least on the first feedback signal and the second feedback signal; and provide the determined parameters to the predistortion circuitry.

Example 2 includes the subject matter of example 1, including or omitting any optional elements, wherein the training circuitry is configured to control the separation circuitry to operate in the first mode to output the amplified training signal; receive the first feedback signal from the receive chain; control the separation circuitry to operate in the second mode to generate the modified amplified training signal; and receive the second feedback signal from the receive chain.

Example 3 includes the subject matter of example 1, including or omitting any optional elements, wherein the separation circuitry includes a phase shifter that is configured to phase shift the amplified training signal by Θ degrees to generate the modified amplified training signal, wherein Θ is other than 0.

Example 4 includes the subject matter of example 3, including or omitting any optional elements, wherein Θ is approximately 180.

Example 5 includes the subject matter of examples 1-4, including or omitting any optional elements, wherein the training circuitry is configured to determine a power amplifier (PA) nonlinearity component and a crosstalk component based on the first feedback signal and the second feedback signal; and determine the parameters based on either the PA nonlinearity component or the crosstalk component.

Example 6 includes the subject matter of example 5, including or omitting any optional elements, wherein the training circuitry is configured to determine the parameters by determining an error between the PA nonlinearity component and the training signal and selecting the parameters to minimize the determined error.

Example 7 includes the subject matter of example 5, including or omitting any optional elements, wherein the training circuitry is configured to, in a first training iteration, estimate model parameters of the crosstalk component and adapt a correction circuitry based on the estimated model parameters of the crosstalk component, wherein the correction circuitry is configured to receive the first feedback signal and generate the PA nonlinearity component. In a second training iteration, the training circuitry is configured to determine an error between the PA nonlinearity component generated by the correction circuitry and the training signal and select the parameters to minimize the determined error.

Example 8 includes the subject matter of example 1, including or omitting any optional elements, wherein the parameters include coefficients that are used by the predistortion circuitry to weight different components of a transmit signal.

Example 9 includes the subject matter of example 1, including or omitting any optional elements, wherein the training circuitry includes a baseband processor configured to execute stored instructions to determine the parameters.

Example 10 includes the subject matter of example 1, including or omitting any optional elements, wherein the separation circuitry includes a switch that is configured to disconnect the amplified training signal from the receive chain to generate the modified amplified training signal.

Example 11 is a method configured to determine parameters for predistortion circuitry in a transceiver including a transmit chain and a receive chain. The method includes providing a training signal to a power amplifier on the transmit chain; controlling a separation circuitry to output the amplified training signal; receiving a first feedback signal from the receive chain; controlling the separation circuitry to output a modified amplified training signal; receiving a second feedback signal from the receive chain; determining parameters based at least on the first feedback signal and the second feedback signal; and providing the determined parameters to the predistortion circuitry.

Example 12 includes the subject matter of example 11, including or omitting any optional elements, wherein the modified amplified training signal includes the amplified training signal phase-shifted by Θ degrees, wherein Θ is other than 0.

Example 13 includes the subject matter of example 12, including or omitting any optional elements, wherein Θ is approximately 180.

Example 14 includes the subject matter of examples 11-12, including or omitting any optional elements, further including determining a power amplifier (PA) nonlinearity component and a crosstalk component based on the first feedback signal and the second feedback signal; and determining the parameters based on either the PA nonlinearity component or the crosstalk component.

Example 15 includes the subject matter of example 11, including or omitting any optional elements, further including determining an error between the PA nonlinearity component and the training signal; and selecting the parameters to minimize the determined error.

Example 16 includes the subject matter of example 14, including or omitting any optional elements, further including, in a first training iteration, estimating model parameters of the crosstalk component and adapting a correction circuitry based on the estimated model parameters of the crosstalk component, wherein the correction circuitry is configured to receive the first feedback signal and generate the PA nonlinearity component; and, in a second training iteration, determining an error between the PA nonlinearity component generated by the correction circuitry and the training signal and selecting the parameters that minimize the determined error.

Example 17 includes the subject matter of example 11, including or omitting any optional elements, wherein the parameters include coefficients that are used by the predistortion circuitry to weight different components of a transmit signal.

Example 18 includes the subject matter of example 11, including or omitting any optional elements, wherein the modified amplified training signal includes a signal in which the amplified training signal is removed.

Example 19 is an apparatus configured to determine parameters for predistortion circuitry in a transceiver including a transmit chain and a receive chain. The apparatus includes means for receiving a first feedback signal that includes an amplified training signal from the receive chain; means for receiving a second feedback signal that includes a modified amplified training signal from the receive chain; means for determining parameters for the predistortion circuitry based at least on the first feedback signal and the second feedback signal; and means for providing the determined parameters to the predistortion circuitry.

Example 20 includes the subject matter of example 19, including or omitting any optional elements, further including means for generating the modified amplified training signal.

Example 21 includes the subject matter of example 19, including or omitting any optional elements, wherein the means for generating includes means for shifting the amplified training signal by Θ degrees, wherein Θ is other than 0.

Example 22 includes the subject matter of example 19, including or omitting any optional elements, wherein the means for generating includes means for disconnecting the amplified training signal from the receive chain.

Various illustrative logics, logical blocks, modules, and circuits described in connection with aspects disclosed herein can be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform functions described herein. A general-purpose processor can be a microprocessor, but, in the alternative, processor can be any conventional processor, controller, microcontroller, or state machine. The various illustrative logics, logical blocks, modules, and circuits described in connection with aspects disclosed herein can be implemented or performed with a general purpose processor executing instructions stored in computer readable medium.

The above description of illustrated embodiments of the subject disclosure, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

In particular regard to the various functions performed by the above described components (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure. In addition, while a particular feature may have been disclosed with respect to only one of several implementations, such feature may be combined with one or more other features of the other implementations as may be desired and advantageous for any given or particular application. The use of the phrase “one or more of A, B, or C” is intended to include all combinations of A, B, and C, for example A, A and B, A and B and C, B, and so on.

1-22. (canceled)

23. A predistortion training system for a predistortion circuitry in a transceiver, comprising:
a separation circuitry configured to:
in a first mode, provide an amplified training signal to a receive chain of the transceiver, wherein the amplified training signal corresponds to a training signal amplified by a power amplifier in a transmit chain of the transceiver; and
in a second mode, process the amplified training signal to generate a modified amplified training signal and provide the modified amplified training signal to the receive chain of the transceiver; and
a training circuitry configured to:
receive a first feedback signal that includes the amplified training signal from the receive chain;
receive a second feedback signal that includes the modified amplified training signal from the receive chain;
determine parameters for the predistortion circuitry based at least on the first feedback signal and the second feedback signal; and
provide the determined parameters to the predistortion circuitry.

24. The predistortion training system of claim 23, wherein the training circuitry is configured to:
control the separation circuitry to operate in the first mode to output the amplified training signal;
receive the first feedback signal from the receive chain;
control the separation circuitry to operate in the second mode to generate the modified amplified training signal; and
receive the second feedback signal from the receive chain.

25. The predistortion training system of claim 23, wherein the separation circuitry comprises a phase shifter that is configured to phase shift the amplified training signal by Θ degrees to generate the modified amplified training signal, wherein Θ is other than 0.

26. The predistortion training system of claim 25, wherein Θ is approximately 180.

27. The predistortion training system of claims 23, wherein the training circuitry is configured to:
determine a power amplifier (PA) nonlinearity component and a crosstalk component based on the first feedback signal and the second feedback signal; and
determine the parameters based on either the PA nonlinearity component or the crosstalk component.

28. The predistortion training system of claim 27, wherein the training circuitry is configured to determine the parameters by:
determining an error between the PA nonlinearity component and the training signal; and
selecting the parameters to minimize the determined error.

29. The predistortion training system of claim 27, wherein the training circuitry is configured to:
in a first training iteration:
estimate model parameters of the crosstalk component; and
adapt a correction circuitry based on the estimated model parameters of the crosstalk component, wherein the correction circuitry is configured to receive the first feedback signal and generate the PA nonlinearity component; and
in a second training iteration:
determine an error between the PA nonlinearity component generated by the correction circuitry and the training signal; and
select the parameters to minimize the determined error.

30. The predistortion training system of claim 23, wherein the parameters comprise coefficients that are used by the predistortion circuitry to weight different components of a transmit signal.

31. The predistortion training system of claim 23, wherein the training circuitry comprises a baseband processor configured to execute stored instructions to determine the parameters.

32. The predistortion training system of claim 23, wherein the separation circuitry comprises a switch that is configured to disconnect the amplified training signal from the receive chain to generate the modified amplified training signal.

33. A method configured to determine parameters for predistortion circuitry in a transceiver including a transmit chain and a receive chain, the method comprising:
providing a training signal to a power amplifier on the transmit chain;
controlling a separation circuitry to output the amplified training signal;
receiving a first feedback signal from the receive chain;
controlling the separation circuitry to output a modified amplified training signal;
receiving a second feedback signal from the receive chain;
determining parameters based at least on the first feedback signal and the second feedback signal; and
providing the determined parameters to the predistortion circuitry.

34. The method of claim 33, wherein the modified amplified training signal comprises the amplified training signal phase-shifted by Θ degrees, wherein Θ is other than 0.

35. The method of claim 34, wherein Θ is approximately 180.

36. The method of claim 14, further comprising:
determining a power amplifier (PA) nonlinearity component and a crosstalk component based on the first feedback signal and the second feedback signal; and
determining the parameters based on either the PA nonlinearity component or the crosstalk component.

37. The method of claim 36, further comprising:
determining an error between the PA nonlinearity component and the training signal; and
selecting the parameters to minimize the determined error.

38. The method of claim 36, further comprising:
in a first training iteration:
estimating model parameters of the crosstalk component; and
adapting a correction circuitry based on the estimated model parameters of the crosstalk component, wherein the correction circuitry is configured to receive the first feedback signal and generate the PA nonlinearity component; and
in a second training iteration:
determining an error between the PA nonlinearity component generated by the correction circuitry and the training signal; and
selecting the parameters that minimize the determined error.

39. The method of claim 33, wherein the parameters comprise coefficients that are used by the predistortion circuitry to weight different components of a transmit signal.

40. The method of claim 33, wherein the modified amplified training signal comprises a signal in which the amplified training signal is removed.

41. An apparatus configured to determine parameters for predistortion circuitry in a transceiver including a transmit chain and a receive chain, the apparatus comprising:
means for receiving a first feedback signal that includes an amplified training signal from the receive chain;
means for receiving a second feedback signal that includes a modified amplified training signal from the receive chain;
means for determining parameters for the predistortion circuitry based at least on the first feedback signal and the second feedback signal; and
means for providing the determined parameters to the predistortion circuitry.

42. The apparatus of claim 41, further comprising means for generating the modified amplified training signal.

43. The apparatus of claim 42, wherein the means for generating comprises means for shifting the amplified training signal by Θ degrees, wherein Θ is other than 0.

44. The apparatus of claim 42, wherein the means for generating comprises means for disconnecting the amplified training signal from the receive chain.
